(19) United States
(12) Patent Application Publication
(10) Pub. No.: US 2020/0144917 A1
(43) Pub. Date: May 7, 2020

(54) VOLTAGE CONVERSION DEVICE HAVING IMPROVED INDUCTOR CURRENT CUTOFF SPEED

(71) Applicant: FALCON SYSTEM CO., LTD., Daejeon (KR)

(72) Inventor: Inyoung CHOI, Daejeon (KR)

(21) Appl. No.: 16/492,088

(22) PCT Filed: Mar. 14, 2018
(86) PCT No.: PCT/KR2018/002996

§ 371 Date: Sep. 6, 2019

(30) Foreign Application Priority Data
Mar. 14, 2017 (KR) 10-2017-0031986

(51) Int. Cl. H02M 3/158; H02M 1/14; G01R 19/165

(52) U.S. Cl. CPC H02M 3/1582; H02M 2001/0009; G01R 19/16576; H02M 1/143

(57) ABSTRACT

A voltage conversion device includes a current measurement means that is installed on a path through which the inductor current flows; a transistor that has a control terminal and an input terminal electrically connected to both ends of the current measurement means, and generates an inductor current cutoff signal when a voltage difference between both ends of the current measurement means exceeds detection set voltage; a reversal maintenance module that controls the charge control element in accordance with the inductor current cutoff signal of the transistor; and a pulse generation module that outputs a trigger pulse to the reversal maintenance module. According to the present invention, since a transistor having a high response speed is used for sensing an inductor current, a simple control is achieved, and even when a voltage of 100 V or higher is supplied, there is a very little amount of excess current.

### BACKGROUND

The present invention relates to a voltage conversion device which converts input voltage and outputs the converted voltage, particularly, a buck converter, and more specifically, to technology including an inductor current control circuit capable of significantly decreasing a current cutoff delay time interfering with inductor current control, and particularly using a high speed transistor as a detection module.

A buck converter shown in FIG. 1 includes a charge control element (Mc), a discharge control element (Md), and an inductor (Lm)). In addition, the characteristics of the inductor are shown in equation 1 which represents currents and equation 2 which represents an accumulated energy.

$$\begin{matrix}V = L \frac{di}{dt} , i = \frac{1}{L} \int V ( t ) dt & Equation 1 \\ W = \int v ( t ) i ( t ) dt = \int i ( t ) L \frac{di}{dt} dt = \frac{1}{2} {Li}^{2} ( t ) & Equation 2\end{matrix}$$

According to the operation of the buck converter, when the charge control element (Mc) is turned on and the discharge control element (Md) Is turned off, the input voltage (Vin) is supplied to the inductor (Lm), so that the current flowing through the inductor is increased. Then, when the charge control element (Mc) is turned off and the discharge control element (Md) Is turned on, the energy charged in the inductor is supplied to the output terminal (Vout). In the buck converter in comparison with a SMPS (Switched Mode Power Supply), since the energy consumed in the charge control element (Mc) is small, there are advantages in that it has a high efficiency, a low standby power, and a simple structure.

In addition, the buck converter control device shown in FIG. 1 can improve a reaction speed according to a load variation. The control device includes a sensing resistance (Rs), a pulse generator (OSC), a current-sense amplifier (CSA), a voltage-error amplifier (VEA), a current-error amplifier (CEA), a pulse-modulation comparator (PWM); a saw-tooth wave generator (SAW), a pulse generator (OSC), and a latch (RS-Latch) in addition to the basic configuration of the buck converter. Here, the illustration of the resistance etc. which controls the gain in FIG. 1 is omitted.

According to the timing diagram shown in FIG. 2, when a pulse is inputted to the s terminal of a latch (RS-Latch) through the pulse generator (OSC), the q terminal becomes high and thus, the charge control element (Mc) is turned on, so that the current is supplied to the inductor (Lm). The increase of the inductor current allows a voltage value to be outputted by the current-sense amplifier (CSA) and current-error amplifier (CEA) serves to output a voltage obtained by subtracting the output value of the voltage-error amplifier (VEA) from the output value of the current-sense amplifier (CSA). When the output voltage of the current-error amplifier (CEA) is higher than the voltage of the saw-tooth wave generator (SAW), the pulse-modulation comparator (PWM) allows the pulse to be generated to the R terminal, so that the Q terminal becomes low and the charge control element is turned off to block the current flowing to the inductor.

The current-sense amplifier (CSA) in the control circuit shown in FIG. 1 serves to provide a linear output in proportion to a difference of the input values. As shown in the circuit diagram of FIG. 3, The current-sense amplifier (CSA) includes an input terminal (310), a compensation terminal (320), and an output terminal (330). The comparator is a high-gain voltage amplifier having a differential amplification input and an infinite output and has a characteristic that the open-loop gain input and the input impedance are very large. In the input terminal (310), a negative input (IN−) is inputted to a control terminal of a first transistor (Q1) and the positive input (IN+) is inputted to the control terminal of a second transistor (Q2). The input current slightly flows into two paths along the I (IN−) and the I (IN+), that is, since the input current does not flow into the output terminal, the input impedance can be increased a lot. The differential input outputs the voltage difference of the two inputs to the compensation terminal as an important structure of the comparator. In addition, the comparator requires a separate power supply and the gain is adjusted by configuring a feedback circuit such as a precise resistor and a capacitor etc. around the periphery thereof. Accordingly, it can be implemented as an inverting amplifier, a non-inverting amplifier, an adder, an oscillator, a differentiation circuit, and as an integrated circuit. Therefore, it is an essential component to implement a circuit capable of four arithmetical operations. The small change of the input signal generates a very large output change owing to the open loop gain structure. Accordingly, a feedback circuit for controlling the same is necessary and the oscillation can be generated by the feedback circuit when the output signal is changed too quickly. In order to prevent the oscillation, the compensation terminal itself limits the output voltage which varies per unit time to set a frequency band suitable for use, which is referred to as a slew rate, which results in a lower reaction speed of the comparator.

According to the operation of the control device shown in FIG. 1, if an error voltage is increased as shown in VEA (out) of FIG. 2, the maximum current of the inductor is increased as I (Lm). Thus, the energy supplied to the output terminal is increased, so that it ensures a rapid response to the load change. To this end, the current-error amplifier serves to output the value obtained by subtracting an error voltage (VEA) from an inductor current measurement value (CSA)). For this arithmetic operation, it uses the comparator as a current sensing element that outputs a difference between the two input voltages in proportion to the output voltage thereof. However, as shown in FIG. 4, a predetermined time is required until a current reduction of the inductor caused by the blocking of the charge control element after sensing the current. It is referred to as a current blocking delay time (Td) and includes the reaction time and latch of the current-sense amplifier (CSA), the current-error amplifier (CEA), and the pulse-modulation comparator (PWM) and the reaction time of the charge control element. The reaction time of the latch and the charge control element is very short to tens of nSec. However, in the case of the comparator, it is very long due to the limit of the slow rate of the output voltage which varies per unit time (in the case of LM358, since the slow rate is 0.3V/us, 10 uSec is required to change 3V). The current blocking delay time generates an excess current (Iex) shown as a line and an amount of excess current shown as a deviant crease line in FIG. 4. For your information, according to the equation 2, the energy stored in the inductor is proportional to the square of the amount of current. In FIG. 4, if the real current charging time (Ts) and the current blocking delay time (Td) are equal, the amount of current is three times as compared to the target value and the energy is about 9 times more, which is fatal.

The excess energy according to the current blocking delay time makes the control of the output voltage very difficult. When the output voltage reaches the target output voltage, if the charge control element is blocked, the control of the gain of each comparator is required to prevent the output voltage from being higher than the target voltage by the excess energy. In order to prevent the output voltage from being changed according to the change of the load, there is a need to adjust the slope of the output signal of the saw-tooth wave generator (SAW). In addition, the excess current does not receive a high voltage. As shown in the equation 1, the slope of the current is V/L. That is, it increases to 10 A per 1 usec when a voltage of 100V is supplied to the inductor having an inductance value of 10 uH. Therefore, when LM358 is used as the comparator, the sequential reaction speed of three comparators (CSA, CEA, PWM) is about 30 usec and the excess current is more than 300 A. However, the allowable current in an actual inductor requires a very large volume. Since the electric current flowing in the electric wire is proportional to the cross sectional area of the electric wire, if the allowable current is increased, the electric wire for winding the iron core becomes thick. For example, when the allowable current is increased by two times, the volume thereof is increased by four or more times. Accordingly, the inductor having the allowable current of 300 A is difficult to be used as a component of a domestic voltage conversion device. In case of a 10 uH inductance, which is commonly used, the volume of the inductor having the allowable current of 10 A is about 12 mm×12 mm×7 mm.

In the voltage conversion device, the efficiency thereof is very important. Usually, the power supplied to the home is an AC power of 100V or more, the SMPS is mainly used as the voltage conversion device. In case of the AC input, a phase difference (T) between a voltage and a current is generated by a coil or a capacitor. Since the electric power is valid in only a current in the same direction as the voltage, the effective power is expressed as voltage×current×COS(T). At this time, if the COS(T) is a power factor, the actual efficiency of the AC voltage conversion device is expressed as power factor×DC efficiency. The SMPS having the advantage of power separation is about 0.4 in terms of the power factor when the rectifier circuit output is directly converted during the AC input. But, after boosting to DC 385V by a power factor correction boost converter, it is known that the power factor is increased to 0.99 by converting the boost converter.

Therefore, the demand of the AC input voltage conversion device using the buck converter in terms of the standby power and the efficiency has been increased. As described above, the input of the high voltage is the largest problem for using the buck converter as the domestic converter. Accordingly, in order to develop the buck converter capable of inputting the high voltage, a wide variety of technologies such as U.S. Pat. No. 5,006,782 “Cascaded buck converter circuit with reduced power loss”, which connects two or more buck converters in series, and U.S. Pat. No. 8,772,967 “Multistage and multiple-output DC-DC converters having coupled inductors”, which connects the buck converters in parallel. However, they are not widely used for commercial use.

The buck converter shown in FIG. 1 can be transformed into a boost converter for performing a boost voltage according to combinations of the inductor, the charge control element, and the discharge control element and a buck-boost converter for generating a reverse voltage. Also, as shown in FIG. 1, the discharge control element (Md) implemented with a transistor can be replaced with a diode, but the efficiency thereof is reduced by the power consumed in the diode.

### SUMMARY OF THE INVENTION

A conventional buck converter has the advantage of very high efficiency, but a current cutoff delay time is long because inductor current is detected using a comparator capable of calculation. As such a current cutoff delay time causes unintended excess current and excess energy, it is necessary to control a gain of each comparator and to control a sawtooth generator or the like. Even when high voltage is input, excess current is increased to a level that the inductor could not afford it so that home use is almost impossible. Accordingly, generally, only voltage of 60 V or lower has been input. For this reason, the buck converter was not used for most demanded household power (AC 100 to 220 V) in spite of the advantage of very high efficiency.

Accordingly, the invention is to make a buck converter as a household voltage transformer by significantly decreasing a current cutoff delay time to minimize excess current and improving efficiency of the buck converter.

According to one aspect of the present invention so as to accomplish these objects, there is provided to a voltage conversion device having an improved inductor current cutoff speed, including an inductor, a charge control element charging current to the inductor, and a discharge control element discharging the current of the inductor, wherein a current control circuit of the inductor including: a current measurement means that is installed on a path through which the inductor current flows; a transistor that has a control terminal and an input terminal electrically connected to both ends of the current measurement means, and generates an inductor current cutoff signal when a voltage difference between both ends of the current measurement means exceeds detection set voltage; a reversal maintenance module that controls the charge control element in accordance with the inductor current cutoff signal of the transistor; and a pulse generation module that outputs a trigger pulse to the reversal maintenance module.

Also, the current measurement means is a sense resistor.

Also, the reversal maintenance module is an RS latch including two negative OR gates, and any one of transistors included in the negative OR gates is electrically connected both ends of the current measurement means.

Also, the voltage conversion device having an improved inductor current cutoff speed further includes an upper limit voltage detection module that generates an inductor current cutoff signal when the output voltage of the voltage conversion device is higher than set voltage.

Also, the reversal maintenance module is an RS latch, and includes an input inspection module that cuts off a charge signal when a cutoff signal of the RS latch is input or a charge state inspection module when the RS latch is in a charge state.

According to the invention, the inductor current cutoff delay time corresponding to several tens of uSec can be reduced to several tens of nSec. Such a short delay time significantly reduces excess current and excess energy. Accordingly, it is possible to control output voltage even with very simple control. Even when high voltage of 100 V or higher is input, the excess current is controlled to the extent that the inductor can handle it. As described above, the buck converter to which high voltage can be used as a household voltage conversion device as it is possible to input AC 100 to 200 V power. Accordingly, there is an effect of solving an energy problem by manufacturing a household voltage conversion device to which a buck converter is applied instead of the existing SMPS.

### BRIEF DESCRIPTION OF DRAWINGS

The above and other objects, features and advantages of the present invention will be more apparent from the following detailed description taken in conjunction with the accompanying drawings, in which:

FIG. 1 is a circuit diagram of a conventional buck converter control circuit;

FIG. 2 is a waveform diagram of a buck converter control circuit according to FIG. 1;

FIG. 3 is a structural diagram of a comparator used in FIG. 1;

FIG. 4 is a waveform diagram showing a current flowing in an inductor of a buck converter;

FIG. 5 is a diagram illustrating a configuration of a voltage conversion device according to a first embodiment of the invention;

FIG. 6 is a diagram illustrating a configuration of a voltage conversion device according to a second embodiment of the invention;

FIG. 7 is a diagram illustrating a waveform of a test result of a control circuit illustrated in FIG. 6;

FIG. 8 is a diagram illustrating a configuration of an inductor current control circuit according to a third embodiment of the invention;

FIG. 9 is a diagram illustrating an inductor current control circuit according to a fourth embodiment of the invention;

FIG. 10 is a diagram illustrating a configuration of an inductor current control circuit according to a fifth embodiment of the invention;

FIG. 11 is a waveform diagram illustrating a test result of the voltage control in FIG. 10;

FIG. 12 is a waveform diagram illustrating an efficiency test result in FIG. 10;

FIG. 13 is a diagram illustrating a configuration of an inductor current control circuit according to a sixth embodiment of the invention;

FIG. 14 is a timing chart of a general RS latch; and

FIG. 15 is a diagram illustrating a configuration of an RS latch control circuit according to a seventh embodiment of the invention.

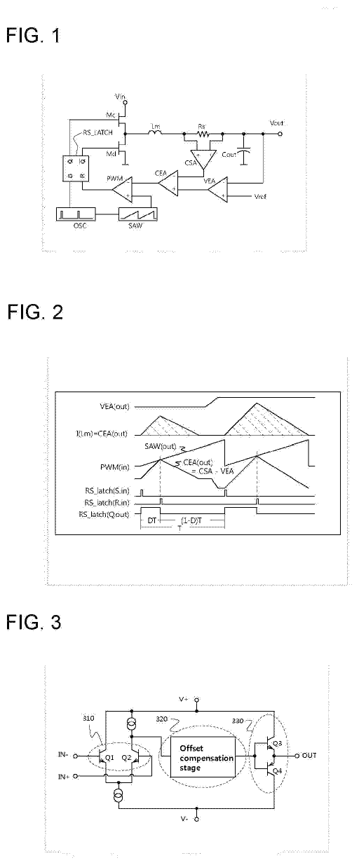

### DETAILED DESCRIPTION OF THE INVENTION

Hereinafter, the invention will be described in more detail with reference to the accompanying drawings. It should be noted that like elements in the drawings are denoted by the same numerals wherever possible. In addition, detailed descriptions of well-known functions and configurations that may unnecessarily obscure the subject matter of the present invention will be omitted.

FIG. 5 is a diagram illustrating a configuration of a voltage conversion device according to a first embodiment of the invention.

The voltage conversion device according to the first embodiment includes a threshold current detection unit (U_TCD), a reversal maintenance module (U_RSLAT), and a pulse generation module (U_TRIG) in addition to the conventional buck converter including a charge control element (Mc), a discharge control element (Dd), an inductor (Lm), and a capacitor (Gout).

The threshold current detection unit (U_TCD) is designed to output low when inductor current is less than “set current” and to output high when the inductor current is more than “set current”, and the output is input to the reversal maintenance module (U_RSLAT) to be used as an inductor current cutoff signal. In the operation of these, when the pulse generation module (U_TRIG) generates a pulse while the output state (Q) of the reversal maintenance module (U_RSLAT) is low, the output state (Q) becomes high to turn on the charge control element (Mc), thereby increasing the inductor current. When the inductor current flows more than the set current, the threshold current detection unit (U_TCD) outputs high to reverse the output state (Q) of the reversal maintenance module (U_RSLAT) to low, thereby cutting off the current flowing to the inductor.

As illustrated in FIG. 5, the threshold current detection unit (U_TCD) includes a sense resistor (Rs) and a detection module (U_DM), and the detection module (U_DM) may be configured with one PNP junction transistor (Qt) (BJT: bipolar junction transistor) in which an input terminal (emitter) and a control terminal (base) are connected to both sides of the sense resistor and an output terminal (collector) is pulled down by a ballast resistor (Rp). In the operation of these, the current of the inductor is reflected to the sense resistor (Rs), and voltage drop occurs between both ends of the sense resistor (Rs) by the reflected current. As the inductor current is increased, voltage difference between both ends of the sense resistor is increased, and when this value is larger than “detection set voltage” of the detection module, the output voltage of the threshold current detection unit (U_TCD) is rapidly increased.

At this time, in detailed operation of the junction transistor (Qt) used as the detection module, current (I (Qt·c), which does not flow when voltage difference between an input terminal and a control terminal is less than threshold voltage and flows from the input terminal to the output terminal when the voltage difference is larger than the threshold voltage, is increased in an exponential function of the voltage difference between the input terminal and the control terminal, and the output voltage is rapidly increased. Accordingly, the detection set voltage of the detection module illustrated in FIG. 5 is the same as the magnitude of the threshold value of the junction transistor. In addition, calculation is impossible in contrast with a comparator in accordance with nonlinear characteristics of a junction transistor, but a high speed junction transistor has an advantage of a fast response speed of 1 nSec or less. In other words, when the response speed of the reversal maintenance module (U_RSLAT) is several nSec or less and the response speed of the charge control element is 10 nSec or less, the inductor current is cut off within 20 nSec from the time of detecting the set current. In other words, the current cutoff delay time is less than 20 nSec.

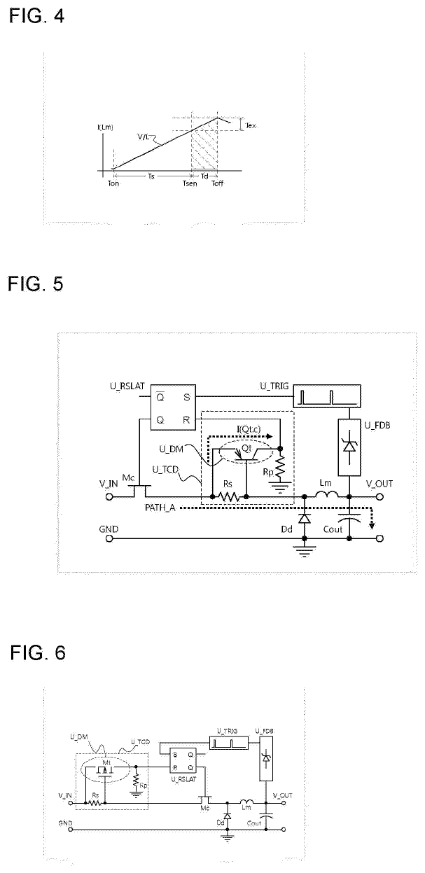

As described above, the fast response speed enables very simple control and input of high voltage. First, since the fast response speed significantly reduce excess current and excess energy based on the current cutoff delay time (Td) illustrated in FIG. 4, compensation for energy such as the existing control method is not necessary. In other words, only the output frequency of the pulse generation module (U_TRIG) is changed in accordance with the change of load, and no special control is necessary. In addition, assuming that the current cutoff delay time is 20 nSec, when 100 V is input to the inductor of 10 uH, the excess current is very small as 0.2 A. Accordingly, even when the input voltage is very high, it is possible to set capacity of the inductor within a reasonable scope.

In addition, when there is no current flow from the input terminal of the detection module to the output terminal thereof, the output terminal of the detection module is in an open state, and an error that voltage is changed by ambient noise may occur. Accordingly, a ballast resistor (Rp) to which minute current is supplied from an ambient current source is absolutely necessary. As the purpose of such a ballast resistor is different from that of the resistor installed for feedback to adjust an open loop gain around the comparator, an accurate resistance value is not necessary.

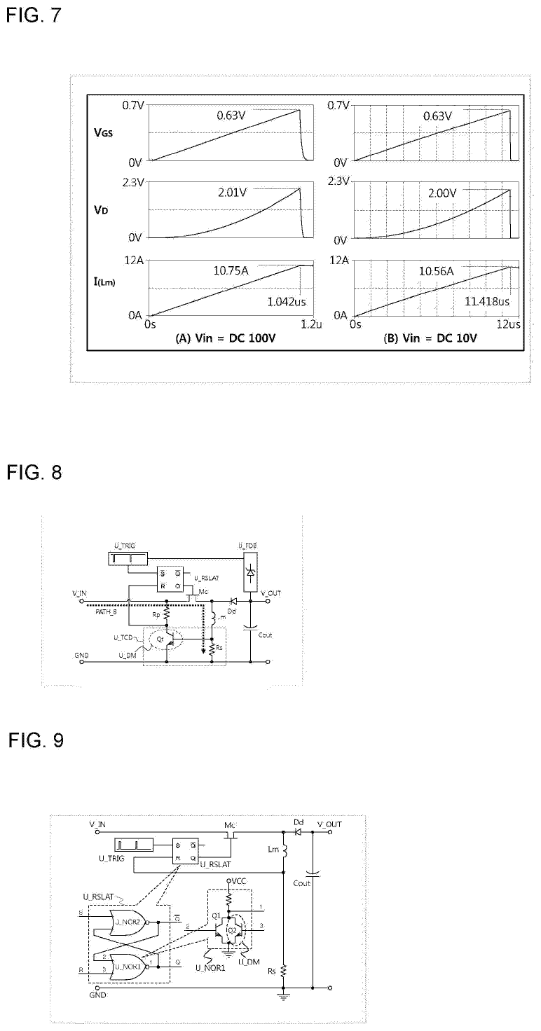

FIG. 6 is a diagram illustrating a configuration of a voltage conversion device according to a second embodiment of the invention, and FIG. 7 is a diagram illustrating a waveform of a test result of a control circuit illustrated in FIG. 6.

In the voltage conversion device according to the second embodiment, the junction transistor used in the first embodiment is changed to a p channel metal oxide semiconductor field effect transistor (MOSFET) and the position of the detection resistor is changed.

In the field effect transistor which controls current (Ids) between the input terminal and an output terminal (drain) by applying voltage to an insulation film between the control terminal (gate) and the input terminal (source), the current (Ids) flowing from the input terminal to the output terminal is proportional to the square of the control voltage (Vgs) when the output voltage is amplified. Since the field effect transistor can adjust threshold voltage and transconductance parameter in accordance with a structure of an insulation film, threshold voltage is determined in accordance with a structure of an insulation film in contrast to the junction transistor determining the threshold voltage in accordance with constituent substances. In the invention, since the threshold voltage is operated with detection set voltage, the field effect transistor shows expandability of changing the detection set voltage. However, precise manufacture is required.

In order to check the operation of the control circuit illustrated in FIG. 6, a test was conducted using an inductor of 10 uH, a sense resistor of 0.06 ohm, and a p channel metal oxide field effect transistor having threshold voltage of 0 V and a transconductance parameter of 0.01 as test environments, and a test result is illustrated in FIG. 7. The test was conducted twice in cases of input voltage of 100 V and 10 V, and the results are illustrated as “(A) Vin=DC 100 V” and “(B) Vin=DC 10 V”. However, in order to illustrate a full waveform, a test time was adjusted to 1.2 uSec and 12 uSec. According to the test results, as the inductor current is increased, the control voltage (Vgs) rises. Accordingly, the output voltage (Vd) is increased in proportional to the square of the control voltage, and it is estimated that a reversal process of the RS latch starts when the output voltage reaches the input voltage (about 2 V) of 74ACT02 used as an element of the RS latch. The maximum current of the inductor which is a matter of interest is 10.75 A and 10.56 A, and the maximum current in the case of high input voltage was measured to be higher by about 0.2 A. Such a test indicates that the field effect transistor with the detection set voltage (threshold voltage) of 0 V can be also used as the detection module when the transconductance parameter is appropriate.

The inductor current measurement means has to be installed on the current path that reflects the rising current of the inductor. Since the charge control element (Mc) and the inductor (Lm) include internal resistance as a parasitic component, the charge control element (Mc) and the inductor (Lm) can be used as the inductor current measurement means, but it is stable to use the sense resistor. In addition, it is helpful for stable operation of the detection module (U_DM) to install the sense resistor (Rs) between the input terminal (V_IN) and the charge control element (Mc) as illustrated in FIG. 6, rather than between the charge control element (Mc) and the inductor (Lm) like the embodiment illustrated in FIG. 5.

FIG. 8 is a diagram illustrating a configuration of an inductor current control circuit according to a third embodiment of the invention.

In the case of the buck converter illustrated in FIG. 5, the current of the charge control element (Mc) flows along a path A (Path A) passing through the inductor (Lm) and the load. When impedance of the load is very large, the inductor current is smaller than the set current of the detection module (U_DM) and the output voltage of the detection module (U_DM) does not rise, in other words, does not generate a cutoff signal. Accordingly, charge control element (Mc) keeps the ON state and the output voltage of the buck converter becomes the same as the input voltage. Such a high voltage output may damage expensive equipment used as a load. In order to prevent this problem, a method of restricting the maximum width of the pulse may be used, but it is possible to solve the problem by applying a buck-booster converter.

Differently from the buck converter illustrated in FIG. 5, in the third embodiment, a buck-booster converter in which the positions of the inductor (Lm) and the discharge control element (Dd) are changed to generate reverse voltage is used.

In the configuration, one of the inductor (Lm) is connected to a charge control element (Mc), the other end thereof is connected to a common terminal (V_GND) through a sense resistor (Rs) constituting a threshold current detection unit, a cathode end of a diode that is a discharge control element (Dd) is connected to a charge switch element (Mc), and an anode end thereof is connected to an output terminal (V_OUT).

An NPN junction transistor is used as the detection module (U_DM), a negative AND (NAND) type RS latch in which the output is reversed at the falling-edge is used instead of the negative OR (NOR) type RS latch illustrated in FIG. 4, and the pulse generation module (U_TRIG) is also changed from rising reaction (high-active) to the falling reaction (low-active).

First, in the operation of the buck-booster converter, when the charge control element (Mc) is turned on, current flows along a path B (Path B) following the inductor (Lm) and the common terminal (V_GND). Thereafter, when the charge control element (Mc) is turned off, the remaining current of the inductor flows from the output terminal (V_OUT) to the common terminal (V_GND), so the voltage of the common terminal is higher than the voltage of the output terminal. In other words, reverse voltage is output. In this case, the load present on the current path B (Path B) of the inductor is only the charge control element and the inductor, and the current of the inductor rises in a slope of Vin/Lm. Such current of the inductor generates the output of the detection module irrespective the impedance of the load, and it is possible to prevent a phenomenon that the output voltage is the same as the input voltage.

In addition, in the operation of the threshold current detection unit (U_TCD), when the current of the inductor (Lm) is lower than the set current, the voltage difference between the input terminal and the control terminal of the detection module (U_DM) is lower than the threshold voltage, the output current does not flow, and high is kept by the ballast resistor (Rp). Thereafter, when the current is higher than the detection set current, the current flows from the input terminal of the detection module (U_DM) to the output terminal thereof, the voltage of the output terminal outputs low equal to the voltage of the common terminal (V_GND), and the output of the negative AND (NAND) type RS latch is reversed by the signal falling as described above to cut off the inductor current.

FIG. 9 is a diagram illustrating an inductor current control circuit according to a fourth embodiment of the invention. In the case of the buck converter illustrated in FIG. 9, one end of current measurement means is directly connected to an R end of a negative OR (NOR) type reversal maintenance module (U_RSLAT). However, a feedback circuit is not illustrated. In this case, the configuration of the reversal maintenance module (U_RSLAT) may include two negative OR gates (U_NOR1 and U_NOR2), and the configuration of the first negative OR gate (U_NOR1) may include two transistors (Q1 and Q2) and one ballast resistor (Rp). In this case, a control terminal (base) of the second transistor (Q2) is electrically connected to one end of the sense resistor (Rs), and an input terminal emitter is electrically connected to the other end of the sense resistor (Rs). In other words, the second transistor of the negative OR gate constituting the reversal maintenance module (U_RSLAT) may be used as the detection transistor. Reversely, this specifies that the reversal maintenance module and the detection module are integrated to be configured only with four transistors and two ballast resistors.

In the inductor current cutoff operation, when the inductor current rises and the voltage of one end of the sense resistor (Rs) rises, the second transistor (Q2) of the first negative OR gate (U_NOR1) rapidly raises the current between the input terminal and the output terminal, and such a signal reverses the output of the reversal maintenance module to cut off the inductor current. In addition, when polarity of the transistor used in the negative OR (NOR) type RS latch is reversed, it becomes a negative AND (NAND) type RS latch. In this case, the transistor constituting the negative AND (NAND) may be used as the detection module. In addition, transistors used as other functions such as AND, OR, NOT, and the like may be used as the detection module.

FIG. 10 is a diagram illustrating a configuration of an inductor current control circuit according to a fifth embodiment of the invention, and presents another example preventing high voltage output by using an upper limit voltage detection module (U_UVF) when the control device illustrated in FIG. 5 generates high voltage. In the configuration, FIG. 10 illustrates a configuration in which an upper voltage detection module (U_UVF) receiving feedback of output voltage and an OR gate to supply this signal to an RS latch like the existing inductor current cutoff signal are added to the inductor current control circuit illustrated in FIG. 5. The upper voltage detection module (U_UVF) includes an upper voltage detection circuit (U_UV1) and a reversal circuit (U_UV2), the upper limit voltage detection circuit (U_UV1) outputs low when voltage higher than set voltage like a feedback circuit (U_FDB), and the set voltage of the upper limit voltage detection circuit (U_UV1) is higher than the set voltage of the feedback circuit (U_FDB).

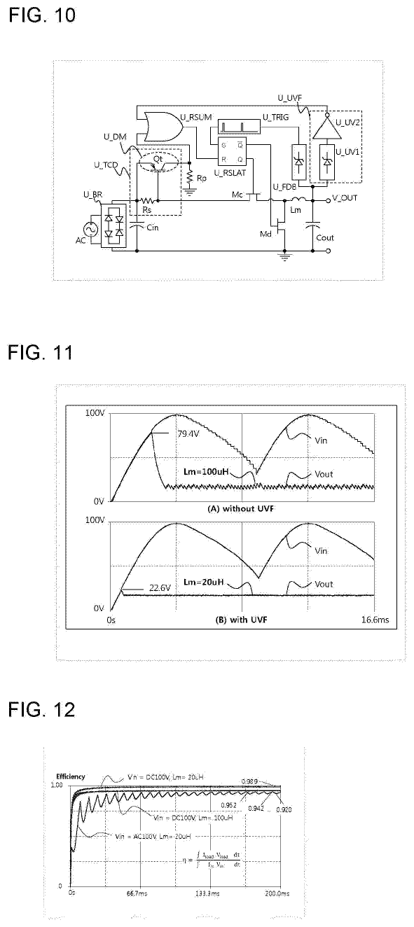

FIG. 11 illustrates a test result of the inductor current control circuit illustrated in FIG. 10 in which input voltage is AC 100 V, set voltage of a feedback circuit (U_FBD) is 15.8 V, and set voltage of an upper limit voltage detection circuit (U_UV1) is 21.5 V, and illustrates comparison of a case (A) with no upper limit voltage detection module (U_UVF) and a case (B) with the upper limit voltage detection module (U_UVF). However, a transistor (Md) was used as a charge control element for an efficiency test, inductances different from each other were set to check an output voltage ripple, a resistor was used as a load, and a value thereof was especially set to control output voltage while input voltage rises.

In the operation according to FIG. 11, voltage is low around polarities (0, π, 2π) of rectified AC 100 V. As illustrated in FIG. 11A, when there is no upper limit voltage detection module (U_UVF) and when resistance of a load is large and input voltage is low in accordance with setting, current flowing in the sense resistor is small, and voltage difference between both ends of the sense resistor is lower than the detection set voltage of the transistor. Since the transistor does not generate an inductor cutoff signal, the reversal maintenance module continues to supply power to the inductor, and the output voltage is the same as the input voltage. In other words, voltage even higher than target voltage (about 15.8 V) is output. Thereafter, when the input voltage is higher than voltage (79.4 V) at which voltage difference between both ends of the sense resistor is larger than the detection set voltage of the transistor, the transistor generates a cutoff signal. Since the inductor current is cut off in accordance with this cutoff signal, it can be seen that the input voltage continues to rise, but the output voltage is controlled to about 16 V. In the case of no load, the output voltage is the same as the input voltage. However, when there is the upper limit voltage detection module (U_UVF), the upper limit voltage detection circuit (U_UV1) outputs low at the moment when the output voltage is over the set voltage 21.5 V of the upper limit voltage detection circuit (U_UV1) even when there is no inductor current cutoff signal of the transistor as illustrated in FIG. 11B, and the reversal circuit (UV2) reverses this signal. Accordingly, a cutoff signal OR circuit (U_RSUM) receives rising voltage, transfers the voltage to the reversal maintenance module (U_RSLAT) to cut off the inductor current, thereby limiting the output maximum voltage to 22.6 V. In the case of no load, charge and cutoff of the inductor current is achieved by the feedback module and the upper limit voltage detection module. Since the upper limit voltage detection does not need to be fast, a comparator may be used and high voltage output may be prevented as being included at the time of current control.

In order to generate high output with less energy, supply has to be frequent. In other words, the output power is inversely proportional to a charge cycle and is proportional to energy per charge cycle. In this case, the energy per charge cycle not only has an influence on an output voltage ripple but also has an important influence on efficiency due to deep relation with power consumption of the charge control element. Since the energy per charge cycle is proportional to inductance, FIG. 11 illustrates an output voltage ripple according to inductance, and FIG. 12 illustrates a value obtained by dividing an integral value of the output power by an integral value of the input power to check efficiency according to inductance. In addition, FIG. 12 further illustrates change of efficiency according to DC or AC input.

In the change of the output voltage ripple according to the energy per charge cycle, as illustrated in FIG. 11, the maximum to minimum voltage of the output voltage ripple is 14 to 18 V in the case of FIG. 11A of large inductor capacity of 100 uH and is 16.5 to 17 V in the case of FIG. 11B of small inductor capacity of 20 uH. According to the test result, when the charge cycle is short and the energy per charge cycle is small, the magnitude of the ripple is decreased and a response speed to the change of output voltage is fast.

In the change of efficiency according to the energy per charge cycle by comparison between a curve of “Vin=DC 100 V, Lm=100 uH” and a curve of “Vin=DC 100 V, Lm=20 uH” illustrated in FIG. 12, the efficiency is 95.2% in the case of inductance of 100 uH, but is increased to 98.9% in the case of inductance of 20 uH. A multiphase buck converter in which inductors are connected in parallel may be used to reduce the energy per charge cycle. Even in such a case, a detection transistor which detects inductor current may be applied. In addition, the energy per charge cycle is changed to inductor capacity and detection set current of the threshold current detection unit, the detection set current is changed to the size of the sense resistor and detection set voltage, and the detection set voltage can be changed by inserting PN junction such as a diode to an input or control terminal of the detection transistor. Accordingly, when the detection modules or the threshold current detection units having detection set current different from each other are disposed in parallel or series and one signal thereof is input to the reversal maintenance module, it is possible to control the output power and the output voltage ripple. Even a comparator which is slow but detects minute voltage difference can be separately disposed to monitor inductor current so that output of high voltage and small current can eb prevented. In addition, a Darlington transistor may be also used as an element which changes detection set voltage of the detection module.

In the change of efficiency according to the AC input by comparison between a curve of “Vin=DC 100 V, Lm=100 uH” and a curve of “Vin=DC 100 V, Lm=20 uH” illustrated in FIG. 12, the efficiency is 98.9% in the case of inputting DC 100 V, but is decreased to about 93% (94.2 to 92.0) in case of inputting AC 100 V. Accordingly, a power factor of the buck converter is high 0.94 (=93/98.9) in contrast to SMPS. Although not illustrated, in the case of “Vin=AC 100 V and Lm=100 uH”, the efficiency converges to about 91%. In addition, when capacity of an input capacitor (Cin) is short, the input voltage of the buck converter may be lower than the output voltage in accordance with characteristics of AC that voltage is periodically lowered. Such reverse voltage generates inductor reverse current flowing from an output capacitor (Cout) to the input capacitor (Cin), and the reverse current decreases efficiency. It is possible to prevent the reverse current from occurring even when the reverse voltage occurs by installing a separate transistor or a diode on an inductor charge current path, but an element may be wasted and efficiency is reduced when a diode is inserted. Accordingly, when the input voltage of the charge control element (Mc) is not so (about 2 to 7 V) higher than (or is lower than) the output voltage of the inductor, a charge signal input to the reversal maintenance module is cut off and a cutoff signal is input to the reversal maintenance module to stop charging the inductor, thereby preventing the reverse current from flowing through the inductor. When such an inductor reverse current control module is applied, charging with a small maximum current amount is continuously repeated to the inductor to increase efficiency in a state where the input voltage of the charge control element (Mc) is slightly higher than the output voltage of the inductor. More specifically, it is more stable to perform control by the input voltage of the sense resistor illustrated in FIG. 10 rather than the control by the input voltage of the charge control element (Mc).

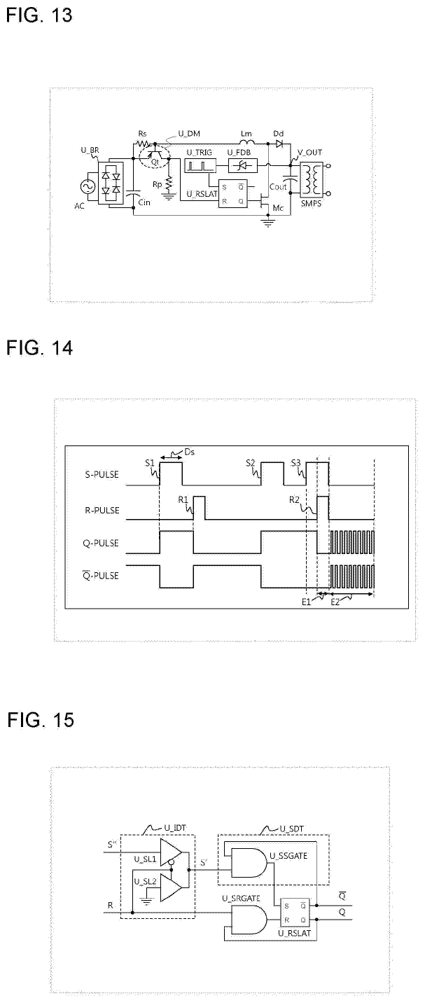

FIG. 13 is a diagram illustrating a configuration of a PFC boost converter in which a detection transistor according to the sixth embodiment of the invention generates an inductor current cutoff signal. As illustrated in FIG. 13, when an inductor (Lm) and a discharge control element (Dd) are connected in series between an input terminal and an output terminal and a charge control element (Mc) is connected to a common terminal therebetween, a boost converter in which output voltage is higher than input voltage is configured. When the output terminal and the common terminal are connected to SMPS, a PFC boost converter is configured. When an input terminal and a control terminal of a detection transistor (Qt) are connected to both ends of a sense resistor (Rs) reflecting current of the inductor at this position and an output signal is connected to an R terminal of a reversal maintenance module (U_RSLAT), it is possible to consistently control the inductor maximum current. Accordingly, it is possible to perform stable control and to reduce capacity and size of the PFC inductor (Lm). However, the boost converter has disadvantages that efficiency is slightly lower than that of the buck converter and the size of the output capacitor (Cout) has to be large. Accordingly, even when the voltage conversion device illustrated in FIG. 10 converts AC into DC and then SMPS changes DC-DC voltage, it is expected that it is possible to embody the same effect as that of the PFC. In addition, when the output voltage of the voltage conversion device illustrated in FIG. 10 is connected to the other buck converter to change the voltage, it is possible to reduce the size of the input capacitor (Cin) smoothing the rectified AC voltage.

FIG. 14 and FIG. 15 are a timing chart of an RS latch according to a seventh embodiment and a diagram illustrating a configuration of an RS latch control circuit, respectively. The purpose of the reversal maintenance module of the voltage conversion device according to the embodiment is to maintain and cut off the inductor charge in response to an S signal and an R signal. A toggle module or the like using a D latch may be used, but an RS latch was used since it is simplest and fastest. In addition, a cutoff signal input to the reversal maintenance module is input after several us to several ms in accordance with input voltage and load from the moment when the charge signal is input, and a width thereof is about several tens of ns in accordance with an operation speed of the charge control element. In other words, it is difficult to accurately predict the input of the cutoff signal.

FIG. 14 is a diagram illustrating a waveform of a general negative OR (NOR) type RS latch, and a Q value is changed only for a normal signal input only when the other end is low such as S1, R1, and S2. However, errors E1 and E2 are generated in invalid inputs such as R2 input when the other end is high. In other words, when an S signal is high and an R signal rises, a defect that Q and nQ ends are simultaneously low occurs such as E1. Even when the S signal and the R signal almost simultaneously fall, a phenomenon that the output of Q goes up and down like E2 occurs. When the RS latch is applied to the voltage conversion device, the defect such as E2 is a critical defect that raises output voltage and current. Accordingly, even when the inductor charge is slightly (several tens to several hundreds of ns) delayed, it does not have an important influence on the output voltage. Accordingly, the voltage conversion device is safer when the charge signal is cut off when both signals of the charge signal (S) and the cutoff signal (R) of the RS latch are high.

FIG. 15 is a diagram illustrating an RS latch control circuit including an input inspection module (U_IDT) and a charge state inspection module (U_SDT) to prevent the defect. First, the input inspection module (U_IDT) includes two latches (U_SL1 and U_SL2). In the operation thereof, when an R signal is high while an S″ signal is high, the cutoff latch (U_SL2) is operated, and a S′ signal becomes low. Thereafter, when an R signal is low, a passing latch (U_SL1) is operated, and the S′ signal and the S″ signal are the same. In other words, the input inspection module (U_IDT) outputs an input of S″ when the R input is low and outputs low when the R input is high, thereby preventing a use limit input in which the S and R inputs are simultaneously high. In addition, when a width (Ds) of a signal generated by the pulse generation module (U_TRIG) illustrated in FIG. 14 is as narrow as possible within the scope in which the RS latch can be set, it is possible to prevent the use limit input. Since the R signal has to be narrow for the same reason, a falling-edge trigger may be used instead of the reversal module (U_UV2) used in FIG. 10.

In addition, the charge state inspection module (U_SDT) includes a charge state inspection circuit (U_SSGATE) receiving S′ and nQ. In the operation there, as illustrated in FIG. 14, it is meaningless and dangerous that a new S′ signal such as S3 is input while the RS latch is in a charge state. Since the nQ output in the charge state is low and the charge state inspection circuit (U_SSGATE) multiples the S′ signal and low and outputs the multiplied value, the S signal is low. In other words, when this is applied to the voltage conversion device according to the embodiment, in the case of low output voltage, the pulse generation module (U_TRIG) generates a charge signal S′. Even when setting of the RS latch is required, the charge signal is removed if the inductor is being charged, and the RS latch is more stably operated. Similarly, an abnormal cutoff signal may be removed by installing a cutoff state inspection circuit U_RSGATE.

For reference, in a method of recovering an error when the error occurs, when Q and nQ are the same value, it is defective. Such a defect is detected by an XOR gate, and the RS latch is recovered when the S input is low, the R input is cut off, the R input is low, and a pulse is supplied to R at intervals. Thereafter, two signals have to be connected after waiting until at least one input of the S and R inputs is low. In addition, initialization of the RS latch, signal delay, and the like are important, but detailed description is omitted. In addition, the control method has been described focusing on cases, but may depend on states. For example, when inductor current is large or output voltage is high in spite of generation of a cutoff signal, this case is a case of failing to cut off the inductor current. Accordingly, a pulse-type cutoff signal may be continuously supplied to the reversal maintenance module until the condition is resolved. In addition, it is possible to predict a state of a load and to control the output voltage by analyzing states such as input voltage and a charge cycle, and an action such as limiting the maximum time of charging the inductor in accordance with conditions may be taken if necessary.

Different from the comparator described in “Background Art”, the transistor used as the detection module of the invention rapidly increases current from the input terminal to the output terminal in accordance with the detection set voltage included therein. Accordingly, calculation cannot be performed, but a feedback circuit is not necessary, and there is no need to limit a response speed. In addition, there is a comparator with a fast response speed such as a slew rate of 1 V/nSec, but a very severe output is generated for ambient noise, and oscillation is more likely to occur. In order to prevent such oscillation, a very precise feedback circuit is necessary.

Accordingly, the fast response speed of the detection module and the stable detection of threshold current are the greatest features of the invention, the junction or field effect transistor was directly used as the detection module in spite of the disadvantages that the output current based on the detection set voltage is output non-linearly such as an exponential function or a square function of the control voltage. In other words, in the invention, the transistor in which the input terminal and the control terminal are connected to both ends of the current measurement means and the input current flows to the output terminal is used as the detection module, differently from the comparator in which current supplied to the input terminal does not flow to the output terminal.

While the present invention has been described with respect to the specific embodiments, it will be apparent to those skilled in the art that various changes and modifications may be made without departing from the spirit and scope of the invention as defined in the following claims.

1. A voltage conversion device having an improved inductor current cutoff speed, including an inductor, a charge control element charging current to the inductor, and a discharge control element discharging the current of the inductor,
wherein a current control circuit of the inductor comprising:
a current measurement means that is installed on a path through which the inductor current flows;
a transistor that has a control terminal and an input terminal electrically connected to both ends of the current measurement means, and generates an inductor current cutoff signal when a voltage difference between both ends of the current measurement means exceeds detection set voltage;
a reversal maintenance module that controls the charge control element in accordance with the inductor current cutoff signal of the transistor; and
a pulse generation module that outputs a trigger pulse to the reversal maintenance module.

2. The voltage conversion device having an improved inductor current cutoff speed according to claim 1, wherein the current measurement means is a sense resistor.

3. The voltage conversion device having an improved inductor current cutoff speed according to claim 1, wherein the reversal maintenance module is an RS latch including two negative OR gates, and any one of transistors included in the negative OR gates is electrically connected both ends of the current measurement means.

4. The voltage conversion device having an improved inductor current cutoff speed according to claim 1, further comprising an upper limit voltage detection module that generates an inductor current cutoff signal when the output voltage of the voltage conversion device is higher than set voltage.

5. The voltage conversion device having an improved inductor current cutoff speed according to claim 1, wherein the reversal maintenance module is an RS latch, and includes an input inspection module that cuts off a charge signal when a cutoff signal of the RS latch is input or a charge state inspection module when the RS latch is in a charge state.
